(19) United States
(12) Patent Application Publication
(10) Pub. No.: US 2002/0090808 A1
(43) Pub. Date: Jul. 11, 2002

(54) Method of manufacturing a self-aligned contact from a conductive layer that is free of voids

(76) Inventors: Jeong-sic Jeon, Hwasung-gun (KR); Gyung-jin Min, Seoul (KR); Wan-jae Park, Suwon-city (KR); Kyeong-koo Chi, Seoul (KR)

Correspondence Address: VOLENTINE FRANCOS, PLLC, SUITE 150, 12200 SUNRISE VALLEY DRIVE, RESTON, VA, 20191, US

(21) Appl. No.: 09/998,928

(22) Filed: Dec. 3, 2001

(30) Foreign Application Priority Data
Dec. 7, 2000 (KR) 00-74317

(51) Int. Cl. H01L 21/4763

(52) U.S. Cl. 438/622

(57) ABSTRACT

A semiconductor device having a self-aligned contact is made by a method in which the conductive layer from which the contact is formed is substantially free of voids. A polysilicon layer mask pattern is formed on an interlayer insulating layer. The interlayer insulating layer is then subjected to a self-aligned contact etching process in which the polysilicon layer mask pattern is used as an etching mask. As a result, a contact hole is formed that exposes a portion of the semiconductor substrate. Next, protective layer spacers are formed at both side walls of the interlayer insulating layer and the mask pattern that define the contact hole. The exposed surface of the semiconductor substrate may then be cleaned. Subsequently, a conductive layer is formed to fill the contact hole. Accordingly, an undercut does not at the interface between the interlayer insulating layer pattern and the mask pattern during the cleaning process. In addition, the conductive material deposits at a uniform rate over the side walls of the interlayer insulating layer and the mask pattern that define the contact hole.

### BACKGROUND OF THE INVENTION

1. Field of the Invention

The present invention relates to a method of manufacturing a semiconductor device. More particularly, the present invention relates to a process of forming a self-aligned contact.

2. Description of the Related Art

As semiconductor devices become more compact and the width of their conductive lines and the spacing between their conductive lines decrease, it becomes more difficult to execute etching processes during the manufacturing of the devices.

Accordingly, a self-aligned contact etching process has been used in the case of manufacturing a semiconductor device having a capacitor, such as a dynamic random access memory (DRAM). More specifically, the self-aligned contact etching process is used to form a buried contact (BC) pad that is to electrically connect a source/drain region and a lower electrode of the capacitor, and a direct contact (DC) pad that is to electrically connect an active region and a bit line.

In the self-aligned contact etching process, a BC contact hole and a DC contact hole are formed in an interlayer insulating layer using an etching mask pattern. Then, a conductive material, for example, polysilicon, is deposited on the semiconductor substrate to form a conductive layer that fills the BC contact hole and the DC contact hole. Next, the conductive layer is polished chemically and mechanically, whereby the BC pad and the DC pad are formed.

However, in this method, the interface between the mask pattern and the interlayer insulating layer can be undercut due to process in which the substrate is cleaned after the contact holes are formed. In addition, the polysilicon deposits on side walls of the mask pattern and the interlayer insulating layer at different rates. Therefore, a void can be formed in the conductive layer adjacent the interface between the mask pattern and the interlayer insulating layer. At least some of this void remains when the contact pad is formed.

### SUMMARY OF THE INVENTION

It is therefore an object of the present invention to solve the above-described problems of the prior art by providing a method of manufacturing a semiconductor device having a self-aligned contact produced from a layer of conductive material that is substantially free of voids.

To achieve this object, the present invention provides protective layer spacers on the sidewalls defining the contact hole in which the self-aligned contact is formed.

In a method of manufacturing a semiconductor device according to the present invention, a conductive pattern is formed on a semiconductor substrate. The conductive pattern may be a gate pattern or a bit line pattern. Subsequently, an interlayer insulating layer is formed on the conductive pattern. The interlayer insulating layer can be formed of silicon oxide or polysilazane (TOSZ). Next, a mask pattern is formed on the interlayer insulating layer. The mask pattern may be formed of polysilicon which has a high etching selectivity with respect to the interlayer insulating layer. Next, a self-aligned contact etching process is performed on the interlayer insulating layer, using the mask pattern as an etching mask, to thereby form an interlayer insulating pattern having a contact hole that exposes a portion of the substrate. At this time, the protective layer spacers are formed on side walls of the mask pattern and the interlayer insulating pattern that define the contact hole. The protective layer spacers can be formed of a silicon oxide layer or a silicon nitride layer. The exposed portion of the semiconductor substrate is then cleaned to remove impurities from the surface thereof. Next, a conductive layer is formed on the semiconductor substrate in order to fill the contact hole. The conductive layer is then planarized to form the contact pad.

The protective layer spacers serve to protect the mask pattern and the interlayer insulating pattern during the cleaning process that is carried out in preparation for the forming of the contact pad. More specifically, a protective layer is formed on the semiconductor substrate. The protective layer is then anisotropically etched to remove portions of the protective layer from the exposed surface of the semiconductor substrate and, at the same time, to leave portions of the protective layer on side walls of the mask and interlayer insulating patterns that define the contact hole.

The protective layer spacers formed in this way prevent undercutting at the interface between the interlayer insulating layer and the mask pattern during the cleaning process. In addition, the protective layer spacers, being of a homogeneous material, form an underlayer that ensures that the conductive material from which the contact pad is formed deposits at a uniform rate. Accordingly, the protective layer spacers prevent a void from being formed in the conductive layer during the deposition of the conductive material used to form the pad.

### BRIEF DESCRIPTION OF THE DRAWINGS

The above and other objects, features and advantages of the present invention will become more apparent by referring to the following detailed description of the preferred embodiments thereof made with reference to the attached drawings, of which:

FIG. 1 is a plan view of a semiconductor device manufactured by a method that incorporates a self-aligned contact etching process according to the present invention;

FIGS. 2A through 7A are cross-sectional views of the semiconductor substrate taken along line a-a of FIG. 1, illustrating a method of manufacturing the semiconductor device according to the present invention;

FIGS. 4B through 7B are cross-sectional views of the semiconductor substrate taken along line a-a of FIG. 1, illustrating a method of manufacturing the semiconductor device according to the present invention;

FIG. 8A is a cross-sectional view of a semiconductor substrate showing the void that is created in the conductive layer, from which a contact pad is to be formed, when protective layer spacers are not employed; and

FIG. 8B is a cross-sectional view of a semiconductor substrate showing the how the conductive layer, from which a contact pad is to be formed, is substantially free of voids when protective layer spacers according to the present invention are employed.

### DETAILED DESCRIPTION OF THE PREFERRED EMBODIMENTS

The present invention will now be described more fully with reference to the accompanying drawings. In the drawings, the thickness of layers and regions are exaggerated for the sake clarity. Also, when a layer is described as being “on” another layer or substrate, such a description means that the layer can be directly on the other layer or substrate, or intervening layers may exist therebetween.

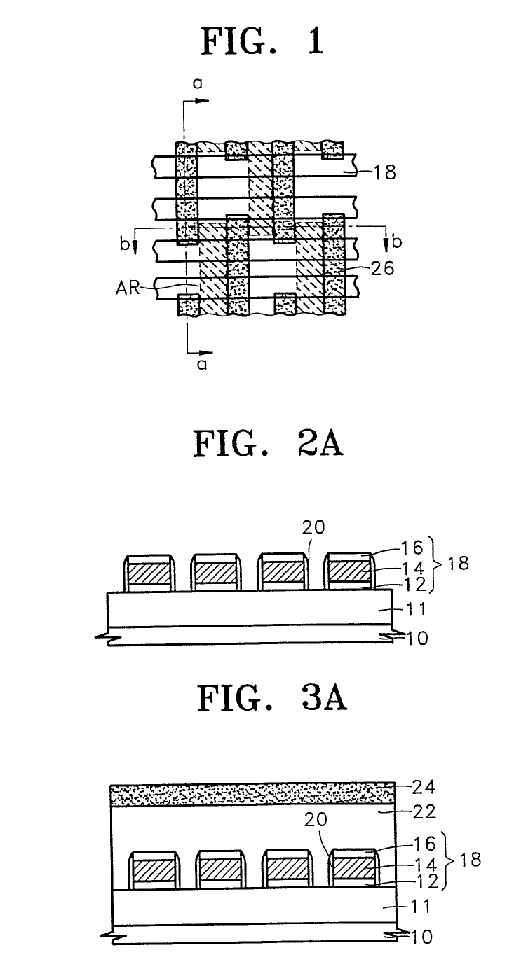

Referring now to FIGS. 1 and 2A, a semiconductor substrate 10, e.g., a silicon substrate has active regions (AR in FIG. 1) and non-active regions. A gate pattern 18 is formed on the semiconductor substrate 10. The gate pattern 18 includes a gate insulating layer 12, a gate electrode 14 and a capping layer 16. The gate insulating layer 12 is a silicon oxide layer. On the other hand, the gate electrode 14 consists of a polysilicon layer and a metal suicide layer such as a tungsten silicide layer. The capping layer 16 is a silicon nitride layer. In FIG. 2A, reference numeral 11 denotes a trench oxide layer. Gate spacers 20 are formed at the side walls of the gate pattern 18 using a silicon nitride layer.

Referring to FIG. 3A, an interlayer insulating layer 22 is formed on the semiconductor substrate 10 on which the gate pattern 18 and the gate spacers 20 have been formed. The interlayer insulating layer 22 can be formed of polysilazane which is a type of spin on glass (SOG). Next, a mask layer 24 is formed on the interlayer insulating layer 22. As will be evident from the description below, the mask layer 24 will be used to form contact holes, such as BC and DC contact holes, that expose the active regions of the semiconductor substrate. The mask layer 24 is a polysilicon layer which enhances the etching profile provided by a subsequent self-aligned contact etching process and provides a high etching selectivity with respect to the silicon nitride of which the capping layer 16 and the gate spacers 20 are formed.

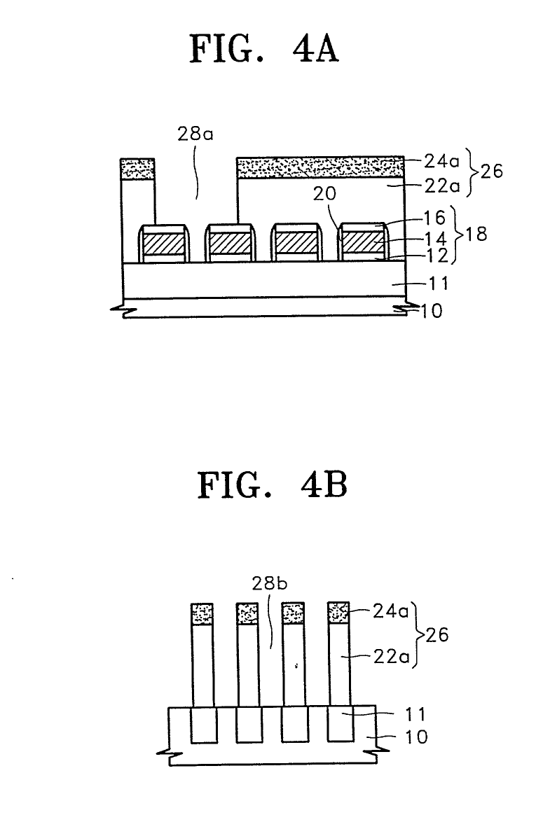

Referring to FIGS. 1, 4A and 4B, a mask pattern 24a is formed by patterning the mask layer 24 through the use of a photo-etching process. A self-aligned contact etching process is performed on the interlayer insulating layer 22 using the mask pattern 24a as an etching mask. As a result of this process, contact holes 28a that expose the active regions of the semiconductor substrate 10 are formed in the interlayer insulating layer 22. Reference numeral 22a denotes the interlayer insulating layer once such a contact hole 28a has been formed therein. The contact hole 28a shown in FIG. 4A serves as a DC contact hole, whereas the contact hole 28b shown in FIG. 4B serves as a BC contact hole. Reference numeral 26 in FIGS. 1, 4A and 4B, denotes the contact hole-forming pattern constituted by the interlayer insulating layer pattern 22a and the mask pattern 24a.

Next, a second etching process is performed to etch away some of the semiconductor substrate. The second etching process removes impurities from the exposed surface the semiconductor substrate 10 and thus, facilitate electrical contact between the substrate 10 and a subsequently formed pad.

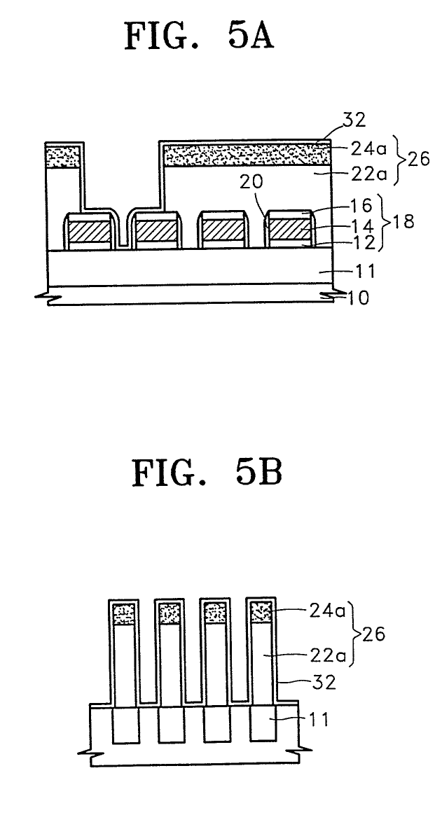

Referring to FIGS. 5A and 5B, a protective layer 32 is formed on the entire surface of the semiconductor substrate 10 on which the mask pattern 24a and the interlayer insulating layer pattern 22a have been formed. The protective layer serves to protect the mask pattern 24a and the interlayer insulating layer 22a from a cleaning process which is carried out before the pad is formed.

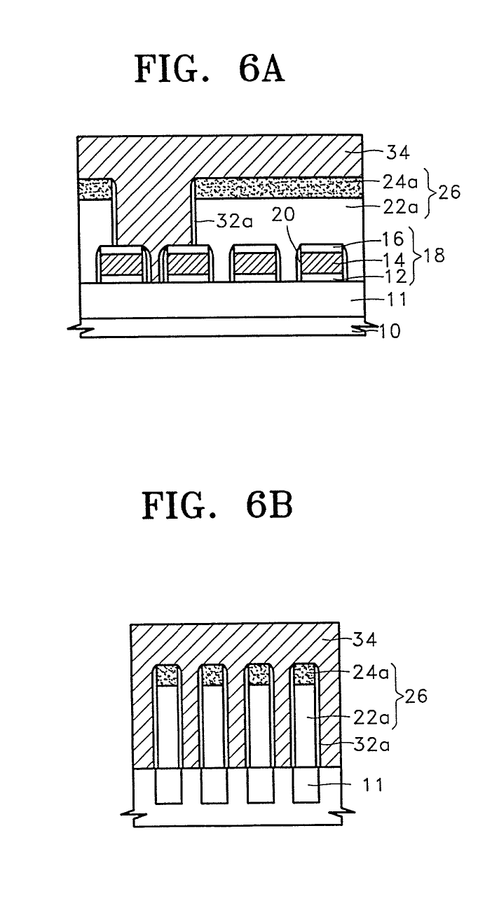

Referring to FIGS. 6A and 6B, the protective layer 32 is anisotropically etched to form protective layer spacers 32a on the side walls of the interlayer insulating layer pattern 22a and the mask pattern 24a. Next, the aforementioned cleaning process is carried out to remove impurities from the semiconductor substrate 10. The cleaning process comprises washing the exposed surface of the substrate 10 with a cleaning solution made of NH₄OH, H₂O₂, and H₂O mixed with an HF solution. According to the present invention, even if the cleaning process is performed, an undercut does not occur because the protective layer spacers 32a prevent the interface between the mask pattern 24a and the interlayer insulating layer pattern 22a from being exposed. Thus, undercutting does not occur when the cleaning process is performed.

Next, a conductive layer 34 is formed on the entire surface of the semiconductor substrate 10. The conductive layer 34 is formed of polysilicon. At this time, voids are not produced in the conductive layer for reasons that will be described later in detail.

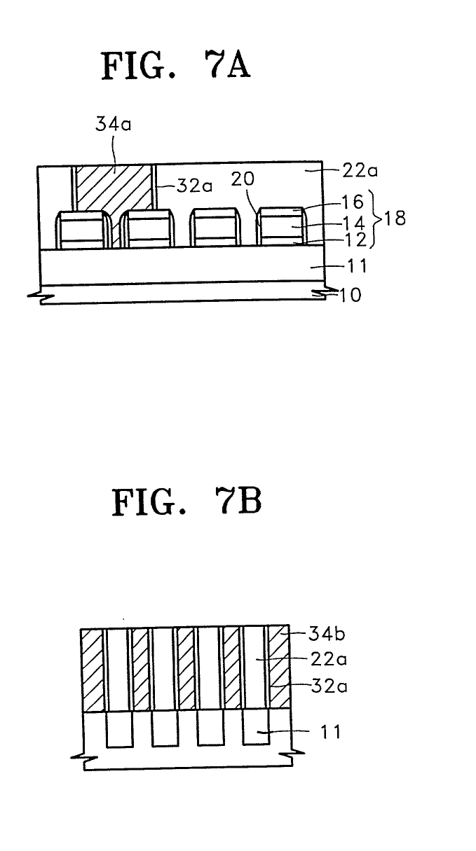

Referring to FIGS. 7A and 7B, with the interlayer insulating layer pattern 22a serving as an etch stop layer, pads (34a, 34b) are formed by etching the conductive layer 34, the mask pattern 24a and the protective layer spacers 32a. In other words, the conductive layer 34 is planarized. The pad 34a shown in FIG. 7A is a DC pad and the pad 34b shown in FIG. 7B is a BC pad. The subsequent processes are the same as those of the conventional method for manufacturing a semiconductor device.

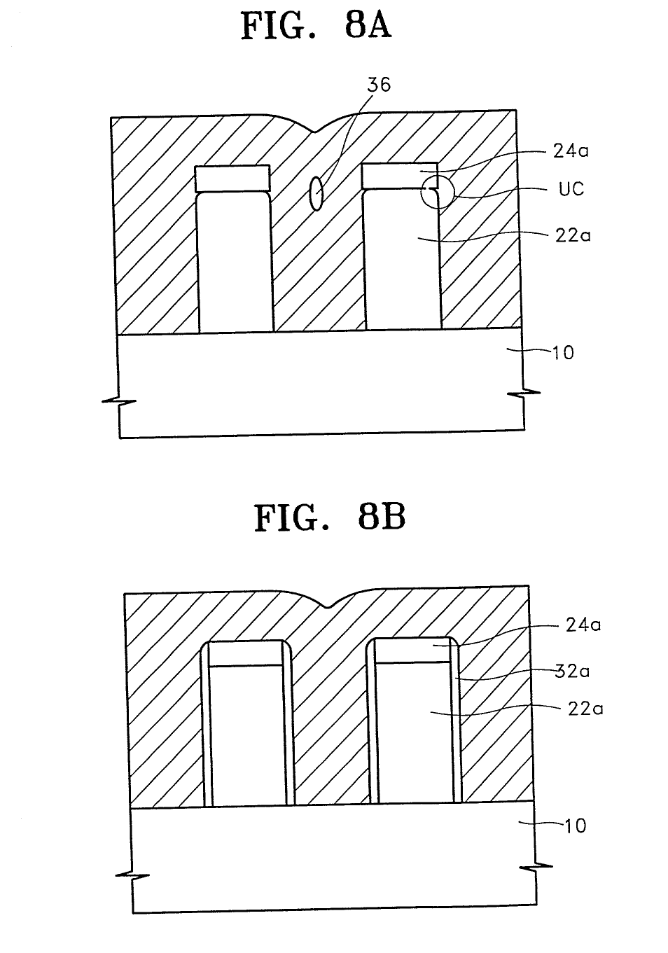

Referring now to FIGS. 8A and 8B, FIG. 8A illustrates a semiconductor device without protective layer spacers 32a, whereas FIG. 8B illustrates a semiconductor device that includes the protective layer spacers 32a according to the present invention. As illustrated in FIG. 8A, if the protective layer spacers 32a are not formed, the interface between the mask pattern 24a and the interlayer insulating layer pattern 22a can be undercut (UC) during the cleaning process because the cleaning solution etches the mask pattern 24a and the interlayer insulating layer pattern 22a at different rates. In addition, the material constituting the conductive layer 34 is deposited at different rates on the underlayer, i.e., the interlayer insulating layer pattern 22a and the mask pattern 24a, because the underlayer comprises different materials. Consequently, a void 36 can be produced in the conductive layer 34.

However, if the protective layer spacers 32a are formed as illustrated in FIG. 8B, an undercut (UC) is not formed at the interface between the mask pattern 24a and the interlayer insulating layer pattern 22a during the cleaning process. Also, the conductive layer 34 is uniformly deposited and grown on the underlayer, i.e., the protective layer spacers 32a, because of the uniformity in the material that constitutes the underlayer. Thus, voids are not formed in the conductive layer 34.

Hence, according to the semiconductor device made according to the present invention as described above, undercutting does not occur at the interface between the interlayer insulating layer pattern and the mask pattern when the surface of the substrate exposed by the contact hole is cleaned in preparation for the forming of the contact pad. Also, the conductive material used to fill the contact hole deposits uniformly over the side walls that define the contact hole. Thus, the present invention prevents voids from forming in the conductive layer during the deposition of the conductive material used to form the contact pad.

Finally, although the present invention has been described above in connection with the preferred embodiments thereof, various changes thereto and modifications thereof will become apparent to those of ordinary skill in the art. For instance, although the present invention has been shown in connection with a gate pattern, the present invention is equally applicable to other conductive patterns such as a bit line pattern. In addition, the second etching process, in which some of the semiconductor substrate is etched away, has been described as being performed before the protective layer spacers are formed. However, the second etching process can be performed after the protective layer spacers 32a are formed or the etching away of some of the semiconductor substrate and the anisotropic etching of the protective layer can be carried out as a single etching process. Therefore, all such changes and modifications that fall within the scope of the appended claims are seen to be within the true spirit and scope of the present invention.

What is claimed is:

1. A method of manufacturing a semiconductor device, comprising the steps of:
forming a conductive pattern on a semiconductor substrate;
forming an interlayer insulating layer on the conductive pattern;
forming a mask pattern of conductive material on the interlayer insulating layer;
etching the interlayer insulating layer using the mask pattern as an etching mask to thereby form a contact hole that exposes a portion of the surface of the semiconductor substrate;
forming protective layer spacers on side walls of the mask pattern and the interlayer insulating layer pattern that define said contact hole;
with said protective layer spacers formed on said side walls, forming a conductive layer, that fills the contact hole, on the entire upper surface of the semiconductor substrate; and
planarizing the conductive layer to form a contact pad, wherein all of the mask pattern is removed to expose a top surface portion of the interlayer insulating layer.

2. The method of manufacturing a semiconductor device of claim 1, and further comprising the step of cleaning said portion of the surface of the substrate to remove impurities from said surface, after the protective layer spacers are formed.

3. The method of manufacturing a semiconductor device of claim 1, and further comprising the step of etching the exposed portion of the surface of the semiconductor substrate, after the interlayer insulating layer pattern is formed, to remove impurities from the surface created by the etching of the interlayer insulating layer.

4. The method of manufacturing a semiconductor device of claim 1, wherein said forming of the protective layer spacers comprises forming a protective layer on the entire surface of the semiconductor substrate including over the mask pattern and the interlayer insulating layer pattern, and subsequently anisotropically etching the protective layer to remove portions of the protective layer from a surface of the semiconductor substrate on which the contact pad is formed.

5. The method for manufacturing a semiconductor device of claim 4, wherein the anisotropic etching of the protective layer is performed to etch the semiconductor substrate as well, and thereby remove impurities from the substrate.

6. The method of manufacturing a semiconductor device of claim 4, and further comprising the step of cleaning the surface of the semiconductor substrate with a cleaning solution after the protective layer spacers are formed.

7. The method of manufacturing a semiconductor device of claim 1, wherein the forming of the mask pattern comprises forming a polysilicon layer, having a high etching selectivity to the interlayer insulating layer, on the interlayer insulating layer.
